(19) United States
(12) Patent Application Publication
(10) Pub. No.: US 2026/0095133 A1
(43) Pub. Date: Apr. 2, 2026

(54) HIGH VOLTAGE SINE TX DRIVER

(71) Applicant: Cypress Semiconductor Corporation, San Jose, CA (US)

(72) Inventors: Sean O'Sullivan, Clonakilty (IE); Cathal O'Lionaird, Cork (IE); Liam Feeney, Cork (IE); Matheus Ferreira Pimenta, Cork (IE)

(73) Assignee: Cypress Semiconductor Corporation, San Jose, CA (US)

(21) Appl. No.: 19/095,433

(22) Filed: Mar. 31, 2025

Related U.S. Application Data
(60) Provisional application No. 63/701,317, filed on Sep. 30, 2024.

(51) Int. Cl. H03F 3/45; H03F 3/26; H04B 1/04

(52) U.S. Cl. CPC H03F 3/45179; H03F 3/26; H03F 3/45475; H04B 1/04; H04B 2001/0408

(57) ABSTRACT

System and methods for implementing a high voltage amplifier that facilitates high voltage multi-phase TX drive. An example integrated circuit may include an operational amplifier including an input stage that operates in a first voltage range and a second voltage range. The operational amplifier includes an output stage that operates in the first voltage range and the second voltage range. The operational amplifier includes a set of extended drain devices coupled between devices of the input stage and the output stage that operate in the first voltage range and the devices of the input stage and the output stage that operation in the second voltage range. The integrated circuit may include a multiplexor coupled to the operational amplifier, where the multiplexor selects between a first sine wave input signal having a first phase or a second sine wave input signal having a second phase as input for the operational amplifier.

### CROSS REFERENCE TO RELATED APPLICATION(S)

This application claims the benefit of and priority to U.S. Provisional Application Ser. No. 63/701,317, entitled “High Voltage Sine TX Driver” and filed on Sep. 30, 2024, which is expressly incorporated by reference herein in its entirety.

### TECHNICAL FIELD

Embodiments of the present disclosure relates generally to the field of electronics, and more particularly, to a high voltage amplifier that facilitates high voltage multi-phase transmission (TX) drive.

### BACKGROUND

Human machine interface (HMI) sensing may rely on measuring deviations from a baseline measurement. In some instances, such as capacitive touch sensing, a touch signal measured may be proportional to an excitation voltage applied to the capacitance electrode. Capacitive touch screen panels may be contacted by a user's finger or stylus pen compatible with capacitive touch screen panels. The touch screen panel may include a transparent and conductive material (e.g., indium tin oxide) that can store electrical charges, and the location of the user's finger or stylus pen contacting the touch screen panel is determined based on the change in the capacitance signal.

### BRIEF DESCRIPTION OF THE DRAWINGS

The described embodiments and the advantages thereof may best be understood by reference to the following description taken in conjunction with the accompanying drawings. These drawings in no way limit any changes in form and detail that may be made to the described embodiments by one skilled in the art without departing from the spirit and scope of the described embodiments.

FIG. 1A illustrates a diagram of an example of a high voltage square wave excitation circuit in accordance with some embodiments of the present disclosure.

FIG. 1B illustrates a diagram of an example of a sine wave excitation circuit in accordance with some embodiments of the present disclosure.

FIG. 2 illustrates a diagram of an example of a high voltage circuit architecture that facilitates high voltage multi-phase TX drive in accordance with some embodiments of the present disclosure.

FIG. 3 illustrates a diagram of an example of an operational amplifier circuit diagram that is part of the high voltage circuit architecture in accordance with some embodiments of the present disclosure.

FIG. 4 is a diagram of an example of an operational amplifier utilized within the integrated circuit of the high voltage circuit architecture in accordance with some embodiments of the present disclosure.

### DETAILED DESCRIPTION

The following description sets forth numerous specific details such as examples of specific systems, components, methods, and so forth, in order to provide a good understanding of various embodiments of the techniques described herein that are specifically designed to facilitates high voltage multi-phase TX drive. It will be apparent to one skilled in the art, however, that at least some embodiments may be practiced without these specific details. In other instances, well-known components, elements, or methods are not described in detail or are presented in a simple block diagram format in order to avoid unnecessarily obscuring the techniques described herein. Thus, the specific details set forth hereinafter are merely exemplary. Particular implementations may vary from these exemplary details and still be contemplated to be within the scope of the present disclosure.

For simplicity of description, many embodiments discussed herein describe an HMI sensing device for detecting when a human finger touches a touch substrate. However, it is understood that any of these embodiments may be configured to detect when any type of substrate touches the touch substrate, as well as to detect/measure level, proximity, presence, gesture, and/or the like.

HMI sensing may rely on measuring deviations from a baseline measurement. In instances of capacitive touch sensing, the touch signal measured may be proportional to an excitation voltage applied to a capacitance electrode. Touch screens may come in the form of in-cell, on-cell, or out-cell. In-cell touch screens include a front glass substrate, a touch sensor layer and liquid crystal display (LCD). In-cell screens may include two layers such that in-cell screens are close to an original screen without the touch screen functions. On-cell touch screens may include a touch film on a top glass substrate which may reduce air and touch layers. Out-cell touch screens may include similar layers as the in-cell and on-cell touch screens but arranged in a different configuration.

In some instances, an organic light emitting diode (OLED) on-cell touch screen includes capacitive sensors that are configured to have the following differences, in comparison to indium tin oxide (ITO) out-cell touch screens, up to five times lower changes in capacitance due to a finger touch, up to 60 times higher capacitance load, or a higher display noise. An increase in the excitation voltage may be utilized in order to maintain signal to noise ratio (SNR) performance for OLED touch screen applications.

Increasing the excitation voltage on the capacitance electrode may be limited, based in part on, technology or electromagnetic emissions. For example, in 5 volt (V) technologies, generating excitation voltages above 5V may be difficult, even when using extended drain devices. In another example, sine wave excitation may be preferred over square wave in order to meet automotive electromagnetic interference (EMI) or electromagnetic compatibility (EMC) standards, which may increase the complexity when designing devices including extended drain devices.

Embodiments of the disclosure address the above-noted and other deficiencies by providing a high-voltage amplifier that facilitates high-voltage multi-phase TX drive. In accordance with embodiments disclosed herein, a high-voltage amplifier may be configured to amplify a 3.2V peak-to-peak sine wave generated by a circuit to at least 8V peak-to-peak, which may facilitate a high-voltage multi-phase TX drive which meets SNR and EMC standards.

HMI sensing involves dealing with small-scale measurements, such as deviations from a baseline measurement. In the case of capacitor sensing, a signal that is received is proportional to an excitation voltage that is applied to a capacitance electrode. There has been a trend to move from ITO or out-cell panels to OLED or on-cell panels, which may presents some challenges. For example, there is approximately five times lower change in capacitance due to a finger touch and up to 60 times higher capacitance load, there may be up to three times higher display noise. In order to maintain the SNR performance that is available with ITO in OLED, the TX circuitry for automotive touchscreen applications should have a high excitation voltage. The TX circuitry may include noise mitigation such as multi-phase TX and low EMC emission.

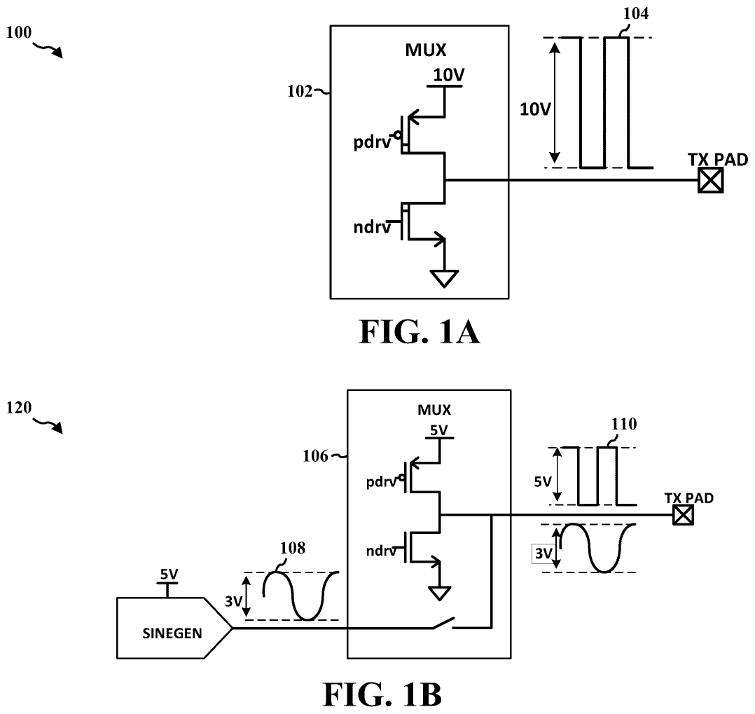

FIG. 1A illustrates a diagram 100 of an example of a high voltage square wave excitation circuit. In some instances, excitation circuits may have a high excitation voltage of 10 volts. However, excitation circuits 102 as shown in diagram 100 of FIG. 1A generate a square wave output signal 104, which risk not meeting ever-tightening EMC standards. The emissions from a square wave signal and all the corresponding harmonics may case driver circuits to fail EMC requirements.

FIG. 1B illustrates a diagram 120 of an example a sine wave excitation circuit. The sine wave excitation circuit 106 of FIG. 1B may be utilized to provide multi-phase TX. Multi-phase TX is configured to excite different electrodes on a panel in different phases. However, the multi-phase TX had only been implemented using a square wave excitation circuit that produced a square wave output signal 110, due in part to use of square wave circuits, which may provide a lot of noise mitigation but at the expense of increasing the SNR. In some instances, mutual capacitance and self capacitance may be utilized with a sine wave excitation circuit 106 with a reduced excitation voltage of a 3 volt input signal 108. The sine wave excitation circuit 106 performed within EMC standards. However, a shift to OLED occurred within the industry and in order for OLED to perform well, there was a need to operate OLED with a high-voltage sine wave excitation circuit capable of doing multi-phase TX.

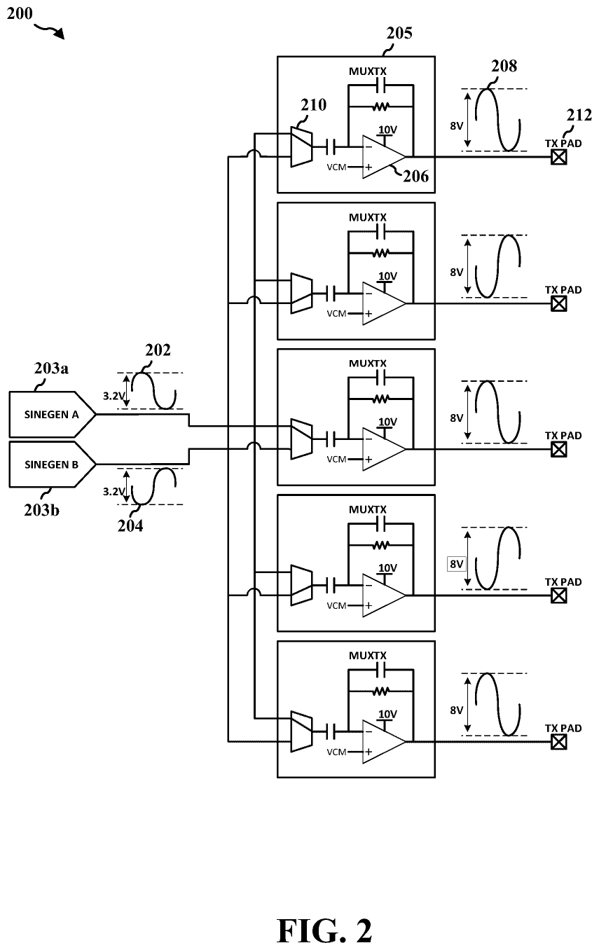

FIG. 2 illustrates a diagram 200 of a high-voltage circuit architecture that facilitates high voltage multi-phase TX drive. The high-voltage circuit architecture is a high-voltage amplifier configured to amplify an input signal 202, 204 (e.g., 3.2 V peak-to-peak sinewave) generated by existing circuitry to an amplified output signal (e.g., at least 8 V peak-to-peak) in order to facilitate the high voltage multi-phase TX drive to meet SNR and EMC standards. The high-voltage circuit architecture may include a plurality of operational amplifier circuits (e.g., MUXTX 205), where each of the plurality of operational amplifier circuits include at least an operational amplifier 206 and a multiplexor 210.

In some embodiments, the high-voltage circuit may select the phase of the input signal 202, 204. The selection of the phase may occur by duplicating the sine wave generation circuit, such that a first sine wave generator 203a generates a first input signal 202 having a first phase, while a second sine wave generator 203b generates a second input signal 204 having a second phase, where the first phase and the second phase are in opposing phases. For example, the first input signal may have a first phase of 0 degrees, such that the second input signal has a second phase of 180 degrees which opposes the first phase of the first input signal. The first and second input signals may have other opposing phases other than 0 and 180 degrees, such that the disclosure is not intended to be limited to the embodiments disclosed herein.

With reference to diagram 200 of FIG. 2, at the open stage, the circuit architecture includes a MUX TX which includes an operational amplifier 206. This operational amplifier is configured to operate based on a 10 volt supply, but may be configured to operate based on various power supplies (e.g., greater than or less than 10 volts) and is not intended to be limited to a 10 volt supply. The operational amplifier receives an input signal (e.g., 202, 204) of 3.2 volts peak-to-peak and is configured to amplify the input signal up from 3.2 volts peak-to-peak to an output signal 208 of eight volts peak-to-peak.

As shown in diagram 200 of FIG. 2, with the input signals (e.g., 202, 204) there is the ability to choose a desired phase. The architecture of FIG. 2 meets the SNR and EMC requirements due in part to the architecture generating a sine wave output signal 208, instead of a square wave, which results in an improved SNR. The amplified output signal is eight volts peak-to-peak instead of five volts peak-to-peak, or three volts peak-to-peak, which essentially doubles the signal and, in turn, doubles the SNR.

At least one advantage of the disclosure is that the operational amplifier amplifies the input signal to eight volts peak-to-peak and generates a sine wave output signal that facilitates the high voltage multi-phase TX drive of the panel. At least one other advantage of the present architecture is it is configured to change the phase, whereas prior circuits would have a low voltage sine wave that was always in the same phase.

Selection of the phase may occur by way of the multiplexor 210. For example, the multiplexor 210, at the input, may have a control bit that can be utilized to instruct the multiplexor which input signal to connect to, such that one of the first phase or the second phase input signals is selected as the input for the operational amplifier. The multiplexor 210 may remain on the selected input signal until instructed to switch. The multiplexor may be configured with a setting that maintains the selected input signal.

In some embodiments, for example as shown in diagram 200 of FIG. 2, the circuit architecture may include multiple operational amplifiers where each operational amplifier has a corresponding multiplexor that provides the corresponding operational amplifier with the selected input signal. In some embodiments, the selected input signals for the operational amplifier may be the same or may be different such that respective output signals of the operational amplifiers are based on the phase of the selected input signals. Each multiplexor may be configured to actively change the phase of the sine wave input to a corresponding operational amplifier. The multiplexors may be programmable to select either of the two input signals. For example, some of the input signals may be in phase and some of the input signal may be out of phase. In some embodiments, the multiplexors can all be enabled and disabled individually. In some embodiments, the multiplexors can be placed into a different mode where they just put out a DC voltage if they're not being used. For example, the multiplexors may enter a floating mode when not in use. In another example, the DC voltage of the multiplexors, when not in use, may be set to ground. The programmability of the multiplexors allows for different input phase signals to be selected while conducting a scan of the touch screen panel. Each TX pad 212 may be connected to a different portion of the touch screen panel, which allows for detection of a location of part of the panel that is being contacted at that particular time.

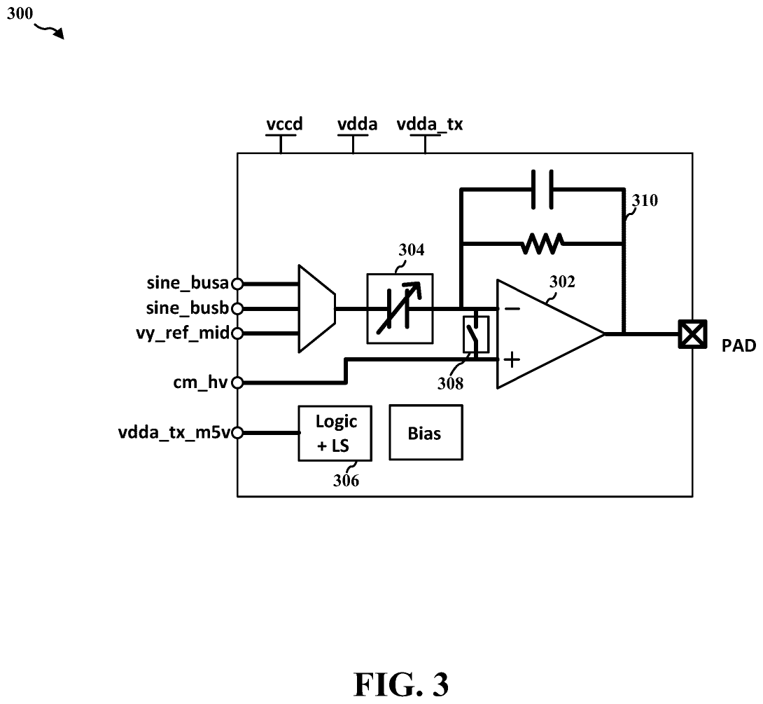

FIG. 3 illustrates a diagram 300 of an operational amplifier circuit that is part of the high-voltage circuit architecture that facilitates high-voltage multi-phase TX drive. In the example operational amplifier circuit of diagram 300, the operational amplifier 302 may include a ten volt class AB operational amplifier. However, in some embodiments, the operational amplifier may include other types of amplifiers and the present disclosure is not intended to be limited to the embodiments disclosed herein. The operational amplifier 302 operates using a ten volt source due, in part, to the operational amplifier 302 including extended drain MOS devices. Extended drain MOS devices can have a voltage between a drain and a source (VDS) that is greater than five volts while the voltage between a gate and the source (VGS) is five volts. The extended drain MOS devices are configured in a dual supply domain, such that all of the p-channel MOS (PMOS) devices in the operational amplifier are operating between 5-10 volts and all the n-channel MOS (NMOS) devices in the operational amplifier are operating between 0-5 volts. The operational amplifier 302 is configured with the dual supply domain to account for technology limitations of the PMOS and NMOS devices. NMOS devices do not normally operate with a VGS/VDS greater than five volts apart from the extended drain devices that can have a VDS of ten volts, but the VGS is limited to five volts. In some embodiments, the operational amplifier 302 is compatible with a three volt supply or a five volt supply.

The operational amplifier circuit of diagram 300 may include a programmable input capacitor 304 coupled to an input of the operational amplifier 302. The programmable input capacitor 304 may be utilized for gain programmability of the operational amplifier. For example, in some instances, the output voltage could be reduced from the amplified voltage of eight volts to a lesser voltage, and the reduction in the amplified output voltage may occur due to the programmable input capacitor 304. In some embodiments, if the power supply includes five volts or 3.3 volts rather than ten volt, the output gain would not be able to achieve the gain as that of the ten volt supply, so a power supply may be clamped by adjusting the programmable input capacitor 304. In some embodiments, the operational amplifier circuit may include very high passive loads such that the linearity of the sine wave may degrade. The programmable input capacitor 304 may be adjusted to reduce the amplitude of the sine wave to improve linearity, which may lead to a reduction of emissions.

The operational amplifier circuit of diagram 300 may include a logic and level shifter component 306. The logic and level shifter component 306 is the component that facilitates the dual supply domain of the operational amplifier 302. The logic and level shifter component 306 ensures that the voltages are biased correctly or that the devices are biased correctly. In some embodiments, digital inputs come into the TX block, and the digital inputs may be either between 0-1.8 volts or between 0-5 volts. The logic and level shifter component facilitates the logic in the operational amplifier, such that the logic may be configured in a dual supply domain. For example, logic may come into the block between 0-1.8 volts. It may then be level-shifted to be either between 0-5 volts or between 5-10 volts.

The operational amplifier circuit of diagram 300 may include a capacitive gain feedback 310 including a resistor and a capacitor, where the capacitive gain feedback is coupled to the output and the input of the operational amplifier. The capacitive gain feedback 310 may support capacitive feedback gain. In some embodiments, the capacitor within the capacitive gain feedback 310 may include a one picofarad (pF) capacitor or a second mode that supports 2.5 pF capacitor, while the resistor may include a five mega-Ohm (M (2) resistor for DC operation. The capacitive gain feedback 310 may couple alternating current (AC) signals.

The operational amplifier circuit of diagram 300 may include a common-mode short switch 308 connected to the inputs of the operational amplifier 302. The common-mode short switch 308 may be utilized in conjunction with the capacitive gain feedback 310 to improve performance or settling time of the operational amplifier 302. The settling time of the operational amplifier 302 may be slow due in part to the high capacitance of the capacitor and the high resistivity of the resistor of the capacitive gain feedback 310. The common-mode short switch 308 shorts the inputs of the operational amplifier 302 which assists in decreasing the settling time of the operational amplifier 302. In some embodiments, the settling time of the operational amplifier 302 may be reduced up to 50% due to the common-mode short switch 308.

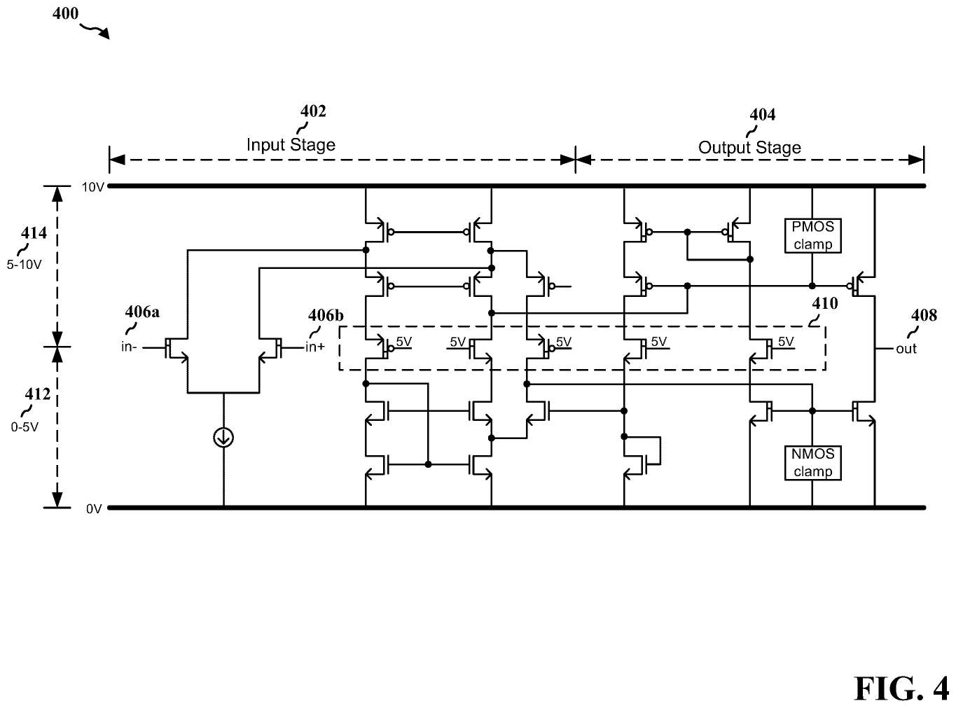

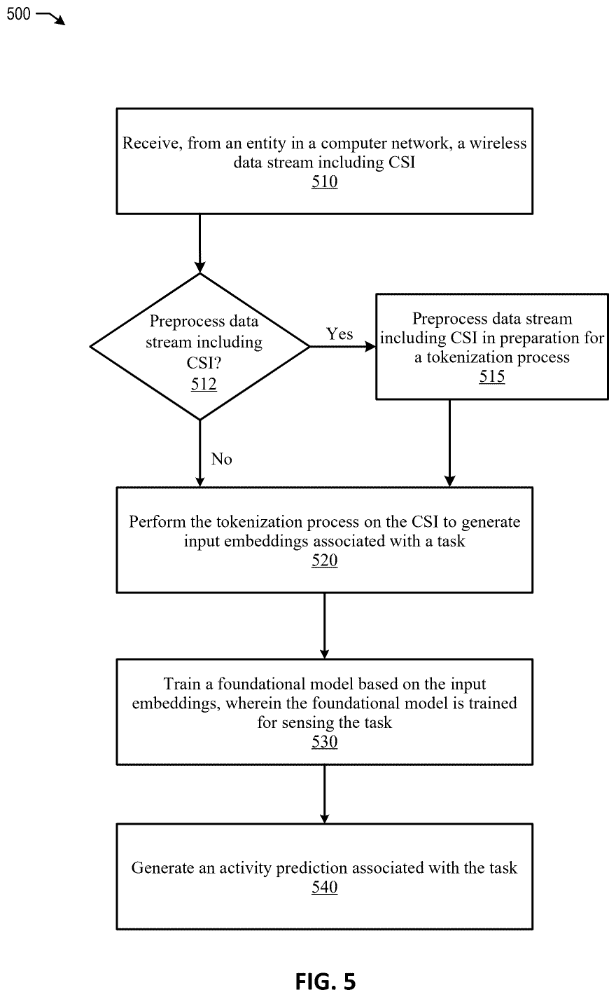

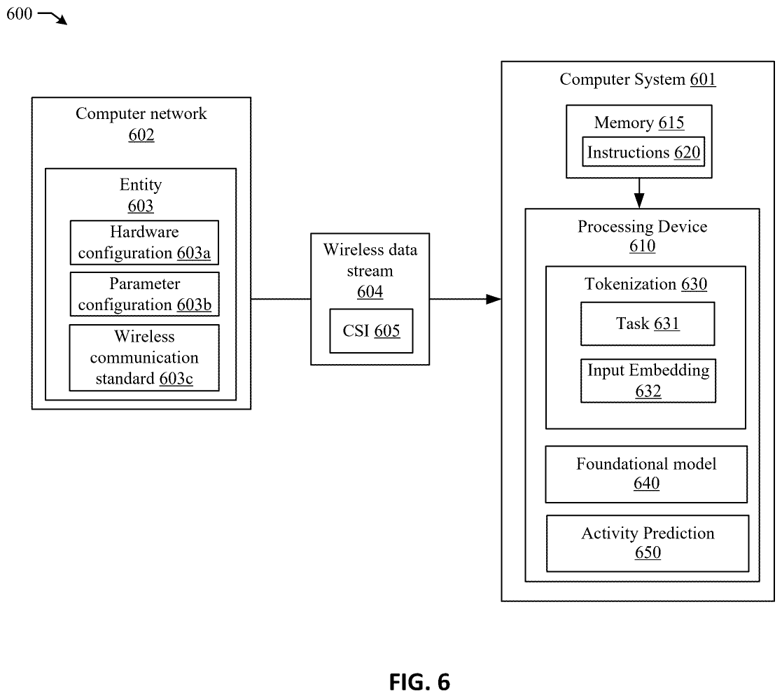

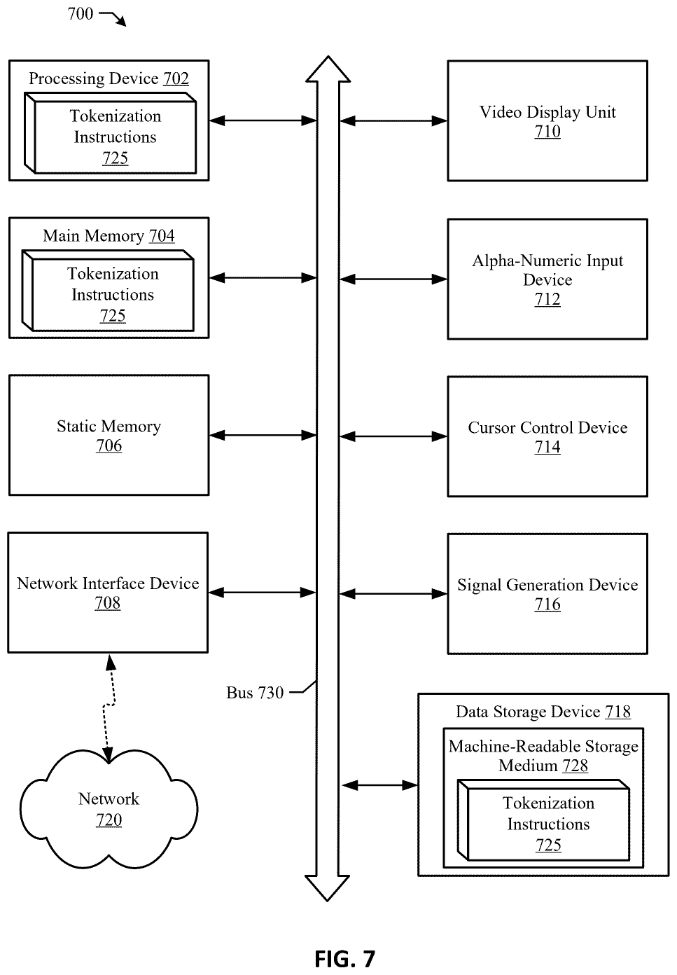

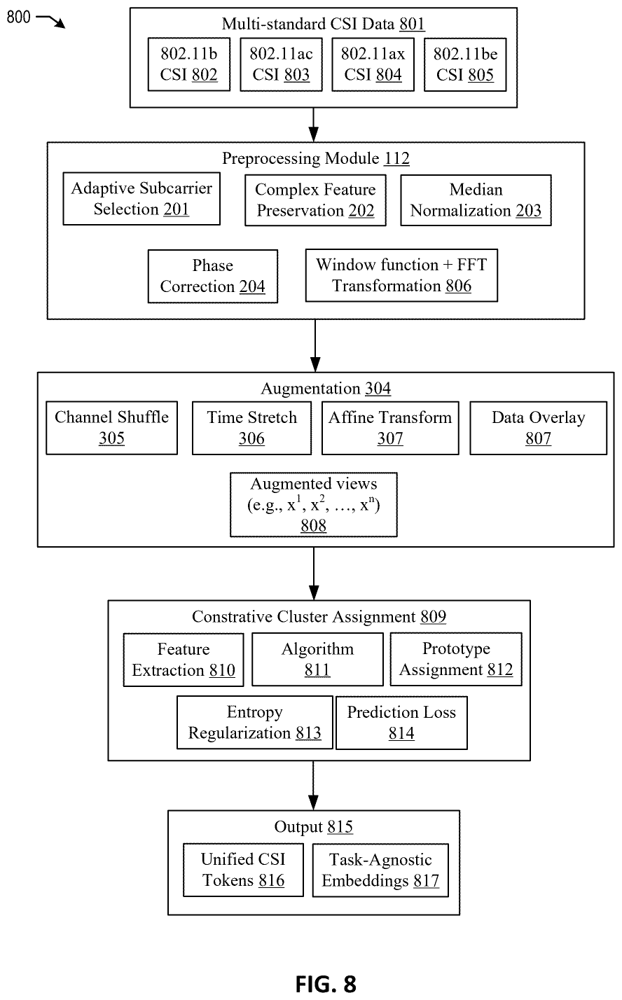

FIG. 4 is a diagram 400 of an example of the operational amplifier utilized within the integrated circuit of the high voltage circuit architecture. The operational amplifier of diagram 400 includes an input stage 402, an output stage 404, negative input terminal 406a, positive input terminal 406b, an output 408, a set of extended drain devices 410. The input stage 402 and the output stage 404 may operate in a first voltage range 412 and a second voltage range 414. The input stage and the output stage may be coupled together to form the operational amplifier. In some embodiments, the input stage includes a folded cascode class A input stage. Devices that include the folded cascade input stage that operate in the first voltage range include at least a negative metal oxide semiconductor (NMOS) transistor. Devices of the folded cascode input stage that operate in the second voltage range include at least a positive metal oxide semiconductor (PMOS) transistor. In some embodiments, the output stage includes a push pull class B output stage with a minimum current selector. Devices that include the push pull output stage that operate in the first voltage range include at least an NMOS transistor. Devices that include the push pull output stage that operation in the second voltage range include at least a PMOS transistor. In some embodiments, the first voltage range 412 may have a range of 0-5 volts, and the second voltage range 414 may have a range of 5-10 volts.

The input terminals (e.g., 406a, 406b) may receive the selected sine wave signal phase as discussed in FIG. 2, and the output 408 may provide an amplified output signal to the TX pad as discussed in FIG. 2 or FIG. 3. In some embodiments, the output of the operational amplifier generates at least an eight volt peak-to-peak sine wave based on a 3.2 volt peak-to-peak input signal.

The set of extended drain devices 410 may be coupled to the input stage and the output stage. The set of extended drain devices 410 couple to the input stage and the output stage may provide an interface between devices of the input stage and the output stage that operate in the first voltage range and devices of the input stage and the output stage that operate in the second voltage range.

The combination of the input stage 402 and the output stage 404 is capable of producing a high output swing without violating the technology limits of the devices within the input stage 402, the output stage 404, or the set of extended drain devices 410. The high output swing may be achieved due in part to the set of extended drain devices 410. Each extended drain device is configured to handle a drain voltage and a source voltage being greater than five volts, whereas non-extended drain devices within the input stage 402 or the output stage 404 are not configured to handle a drain voltage and a source voltage being greater than five volts, such that the non-extended drain devices of the input stage or the output stage cannot have a voltage delta more than five volts.

The first voltage range 412 may include the NMOS portion such that devices within the NMOS portion operate between 0-5 volts. The second voltage range 414 may include the PMOS portion such that devices within the PMOS portion operate between 5-10 volts. The first voltage range 412 and the second voltage range 414 may be separated by the set of extended drain devices 410. The set of extended drain devices 410 separates the devices within the first voltage range 412 and the second voltage range 414 from being exposed to each other. For example, the set of extended drain devices 410 may be activated which causes a voltage drop of approximately 5 volts. The voltage drop caused by the set of extended drain devices 410 prevents a high voltage from a device operating in the second voltage range 414 from being exposed to devices that operate within the first voltage range 412. A device that operates in the first voltage range being exposed to a voltage from the second voltage range may cause such device to fail. As such, the set of extended drain devices 410 may prevent exposure of low voltage devices to high voltages. The operational amplifier includes the dual supply domain based on devices that operate in the first voltage range and the second voltage range, but is configured to produce a 0-10 volt peak-to-peak sign wave at the output 408.

At least one advantage of the disclosure is that the operational amplifier is a ten volt operational amplifier that has a dual supply domain, where the operational amplifier is using five volt devices to produce an output swing that is greater than five volts. The operational amplifier may produce the output swing that is greater than five volts due in part to the set of extended drain devices.

In the above description, some portions of the detailed description are presented in terms of algorithms and/or symbolic representations of operations on analog signals and/or digital signals or data bits within a non-transitory storage medium. These algorithmic descriptions and representations are the means used by those skilled in the data processing arts to most effectively convey the substance of their work to others skilled in the art. An algorithm is here and generally, conceived to be a self-consistent sequence of steps leading to a desired result. The steps are those requiring physical manipulations of physical quantities. Usually, though not necessarily, these quantities take the form of electrical or magnetic signals capable of being stored, transferred, combined, compared and otherwise manipulated. It has proven convenient at times, principally for reasons of common usage, to refer to these signals as bits, values, elements, symbols, characters, terms, numbers, or the like.

Reference in the description to “an embodiment,” “one embodiment,” “an example embodiment,” “some embodiments,” and “various embodiments” means that a particular feature, structure, step, operation, or characteristic described in connection with the embodiment(s) is included in at least one embodiment of the disclosure. Further, the appearances of the phrases “an embodiment,” “one embodiment,” “an example embodiment,” “some embodiments,” and “various embodiments” in various places in the description do not necessarily all refer to the same embodiment(s).

The description includes references to the accompanying drawings, which form a part of the detailed description. The drawings show illustrations in accordance with exemplary embodiments. These embodiments, which may also be referred to herein as “examples,” are described in enough detail to enable those skilled in the art to practice the embodiments of the claimed subject matter described herein. The embodiments may be combined, other embodiments may be utilized, or structural, logical, and electrical changes may be made without departing from the scope and spirit of the claimed subject matter. It should be understood that the embodiments described herein are not intended to limit the scope of the subject matter but rather to enable one skilled in the art to practice, make, and/or use the subject matter.

It should be borne in mind, however, that all of these and similar terms are to be associated with the appropriate physical quantities and are merely convenient labels applied to these quantities. Unless specifically stated otherwise as apparent from the above discussion, it is appreciated that throughout the description, discussions utilizing terms such as “receiving,” “performing,” “detecting,” “providing,” “generating,” “adjusting,” “determining,” or the like, refer to the actions and processes of an integrated circuit (IC) controller, or similar electronic device, that manipulates and transforms data represented as physical (e.g., electronic) quantities within the controller's registers and memories into other data similarly represented as physical quantities within the controller memories or registers or other such information non-transitory storage medium.

The words “example” or “exemplary” are used herein to mean serving as an example, instance, or illustration. Any embodiment or design described herein as “example’ or “exemplary” is not necessarily to be construed as preferred or advantageous over other embodiments or designs. Rather, use of the words “example” or “exemplary” is intended to present concepts in a concrete fashion. As used in this application, the term “or” is intended to mean an inclusive “or” rather than an exclusive “or.” That is, unless specified otherwise, or clear from context, “X includes A or B” is intended to mean any of the natural inclusive permutations. That is, if X includes A; X includes B; or X includes both A and B, then “X includes A or B” is satisfied under any of the foregoing instances. In addition, the articles “a” and “an” as used in this application and the appended claims should generally be construed to mean “one or more” unless specified otherwise or clear from context to be directed to a singular form. Moreover, use of the term “an embodiment” or “one embodiment” or “an embodiment” or “one embodiment” throughout is not intended to mean the same embodiment or embodiment unless described as such.

Embodiments described herein may also relate to an apparatus (e.g., high voltage sine TX driver system/circuit) for performing the operations herein. This apparatus may be specially constructed for the required purposes, or it may include firmware or hardware logic selectively activated or reconfigured by the apparatus. Such firmware may be stored in a non-transitory computer-readable storage medium, such as, but not limited to, read-only memories (ROMs), random access memories (RAMs), EPROMS, EEPROMs, flash memory, or any type of media suitable for storing electronic instructions. The term “computer-readable storage medium” should be taken to include a single medium or multiple media that store one or more sets of instructions. The term “computer-readable medium” shall also be taken to include any medium that is capable of storing, encoding, or carrying a set of instructions for execution by the machine and that causes the machine to perform any one or more of the methodologies of the present embodiments. The term “computer-readable storage medium” shall accordingly be taken to include, but not be limited to, solid-state memories, optical media, magnetic media, any medium that is capable of storing a set of instructions for execution by the machine and that causes the machine to perform any one or more of the methodologies of the present embodiments.

The above description sets forth numerous specific details such as examples of specific systems, components, methods, and so forth, in order to provide a good understanding of several embodiments of the present disclosure. It is to be understood that the above description is intended to be illustrative and not restrictive. Many other embodiments will be apparent to those of skill in the art upon reading and understanding the above description. The scope of the disclosure should, therefore, be determined with reference to the appended claims, along with the full scope of equivalents to which such claims are entitled.

Various units, circuits, or other components may be described or claimed as “configured to” or “configurable to” perform a task or tasks. In such contexts, the phrase “configured to” or “configurable to” is used to connote structure by indicating that the units/circuits/components include structure (e.g., circuitry) that performs the task or tasks during operation. As such, the unit/circuit/component can be said to be configured to perform the task, or configurable to perform the task, even when the specified unit/circuit/component is not currently operational (e.g., is not on). The units/circuits/components used with the “configured to” or “configurable to” language include hardware—for example, circuits, memory storing program instructions executable to implement the operation, etc. Reciting that a unit/circuit/component is “configured to” perform one or more tasks, or is “configurable to” perform one or more tasks, is expressly intended not to invoke 35 U.S.C. § 112(f) for that unit/circuit/component. Additionally, “configured to” or “configurable to” can include generic structure (e.g., generic circuitry) that is manipulated by software and/or firmware (e.g., an FPGA or a general-purpose processor executing software) to operate in manner that is capable of performing the task(s) at issue. “Configured to” may also include adapting a manufacturing process (e.g., a semiconductor fabrication facility) to fabricate devices (e.g., integrated circuits) that are adapted to implement or perform one or more tasks. “Configurable to” is expressly intended not to apply to blank media, an unprogrammed processor or unprogrammed generic computer, or an unprogrammed programmable logic device, programmable gate array, or other unprogrammed device, unless accompanied by programmed media that confers the ability to the unprogrammed device to be configured to perform the disclosed function(s).

The foregoing description, for the purpose of explanation, has been described with reference to specific embodiments. However, the illustrative discussions above are not intended to be exhaustive or to limit the present disclosure to the precise forms disclosed. Many modifications and variations are possible in view of the above teachings. The embodiments were chosen and described in order to best explain the principles of the embodiments and its practical applications, to thereby enable others skilled in the art to best utilize the embodiments and various modifications as may be suited to the particular use contemplated. Accordingly, the present embodiments are to be considered as illustrative and not restrictive, and the present disclosure is not to be limited to the details given herein, but may be modified within the scope and equivalents of the appended claims.

What is claimed is:

1. An integrated circuit, comprising:
an operational amplifier, comprising:
an input stage configured to operate in a first voltage range and a second voltage range;
an output stage configured to operate in the first voltage range and the second voltage range, wherein the input stage and the output stage are coupled together; and
a set of extended drain devices coupled to the input stage and the output stage to interface between devices of the input stage and the output stage that operate in the first voltage range and the devices of the input stage and the output stage that operate in the second voltage range; and
a multiplexor coupled to the operational amplifier, wherein the multiplexor receives a first sine wave input signal having a first phase and a second sine wave input signal having a second phase, wherein the multiplexor is configured to select between the first sine wave input signal or the second sine wave input signal as input for the operational amplifier.

2. The integrated circuit of claim 1, wherein the input stage comprises a folded cascode input stage.

3. The integrated circuit of claim 2, wherein the devices of the folded cascode input stage that operate in the first voltage range comprise at least a negative metal oxide semiconductor (NMOS) transistor.

4. The integrated circuit of claim 3, wherein the devices of the folded cascode input stage that operate in the second voltage range comprise at least a positive metal oxide semiconductor (PMOS) transistor.

5. The integrated circuit of claim 1, wherein the output stage comprises a push pull output stage.

6. The integrated circuit of claim 5, wherein the devices of the push pull output stage that operate in the first voltage range comprise at least a negative metal oxide semiconductor (NMOS) transistor.

7. The integrated circuit of claim 6, wherein the devices of the push pull output stage that operation in the second voltage range comprise at least a positive metal oxide semiconductor (PMOS) transistor.

8. The integrated circuit of claim 1, wherein a low end of the second voltage range is greater than a high end of the first voltage range.

9. The integrated circuit of claim 8, wherein the first voltage range is zero to five volts, wherein the second voltage range is five to ten volts.

10. The integrated circuit of claim 1, further comprising:
a programmable input device coupled to the input stage, wherein the programmable input device is configured to vary a gain of the operational amplifier.

11. The integrated circuit of claim 10, wherein the programmable input device comprises a programmable input capacitor.

12. The integrated circuit of claim 1, further comprising:
a feedback system coupled to an output of the operational amplifier and an input of the operational amplifier, wherein the feedback system provides a capacitive feedback gain.

13. The integrated circuit of claim 1, wherein the multiplexor is coupled to an input of the operational amplifier and configured to receive the first sine wave input signal having the first phase, the second sine wave input signal having the second phase, or a direct current (DC) reference input signal.

14. The integrated circuit of claim 13, wherein the first phase and the second phase are different, wherein the DC reference input signal maintains DC operation of the integrated circuit.

15. The integrated circuit of claim 13, wherein the multiplexor is configured to switch between the first sine wave input signal and the second sine wave input signal to change a phase of an output signal from the output of the operational amplifier.

16. The integrated circuit of claim 1, further comprising:
a common-mode short switch coupled to the input of the operational amplifier, wherein the common-mode short switch is configured to reduce a settling time of the operational amplifier.

17. The integrated circuit of claim 1, further comprising:
a logic shifter and a level shifter, wherein the logic shifter and the level shifter are configured to facilitate a dual supply domain operation of the operational amplifier.

18. The integrated circuit of claim 1, wherein an output of the operational amplifier generates at least an eight volt peak-to-peak sine wave based on a 3.2 volt peak-to-peak input signal.

19. A method, comprising:
receiving at least one of a first sine wave input signal having a first phase or a second sine wave input signal having a second phase;
selecting the at least one of the first sine wave input signal or the second sine wave input signal as input for an operational amplifier;
amplifying the input at an input stage of the operational amplifier, where the input stage operates in a first voltage range and a second voltage range; and
outputting an amplified output signal at an output stage of the operational amplifier, where the output stage operates in the first voltage range and the second voltage range.

20. A system, comprising:
a multiplexor configured to select at least one of a first sine wave input signal having a first phase or a second sine wave input signal having a second phase as an input signal; and
an operational amplifier coupled to the multiplexor configured to:
receive the input signal from the multiplexor;
amplify the input signal at an input stage of the operational amplifier, where the input stage operates in a first voltage range and a second voltage range; and
output an amplified output signal at an output stage of the operational amplifier, where the output stage operates in the first voltage range and the second voltage range.
